(19) United States
(12) Patent Application Publication
(10) Pub. No.: US 2025/0374424 A1
(43) Pub. Date: Dec. 4, 2025

(54) WIRING BOARD, SEMICONDUCTOR DEVICE, LIGHT EMITTING DEVICE, METHOD OF MANUFACTURING WIRING BOARD, AND METHOD OF MANUFACTURING LIGHT EMITTING DEVICE

(71) Applicants: AOI ELECTRONICS CO., LTD., Kagawa (JP); NICHIA CORPORATION, Tokushima (JP)

(72) Inventors: Takaaki KATO, Kagawa (JP); Yuzuru SHISHIDO, Kagawa (JP); Shinichi DAIKOKU, Tokushima-shi (JP); Tomohide MIKI, Tokushima-shi (JP); Yasuo KATO, Nagoya-shi (JP); Masashi ISHIDA, Anan-shi (JP); Eiko MINATO, Anan-shi (JP)

(21) Appl. No.: 19/219,423

(22) Filed: May 27, 2025

(30) Foreign Application Priority Data
May 28, 2024 (JP) 2024-086410

(51) Int. Cl. H05K 1/02; H05K 1/11; H05K 1/18; H05K 3/06

(52) U.S. Cl. CPC H05K 1/0298; H05K 1/11; H05K 1/18; H05K 3/06; H05K 2201/10106; H05K 2201/10121

(57) ABSTRACT

A wiring board includes an insulating substrate, a base layer arranged on an upper surface of the insulating substrate, a first metal layer arranged on an upper surface of the base layer and containing a first metal, a second metal layer arranged on an upper surface of the first metal layer and containing a second metal less noble than the first metal, a third metal layer arranged on an upper surface and a side surface of the second metal layer and containing the first metal, and a fourth metal layer arranged on an upper surface and a side surface of the third metal layer and containing a third metal more noble than the first metal, and an entire surface of the second metal layer is covered with the first metal layer and the third metal layer.

### CROSS REFERENCES TO RELATED APPLICATIONS

The present application claims priority to Japanese Patent Application No. 2024-086410 filed on May 28, 2024, the disclosure of which is incorporated herein by reference.

### BACKGROUND

### 1. Technical Field

The present invention relates to a wiring board, a semiconductor device, a light emitting device, a method of manufacturing a wiring board, and a method of manufacturing a light emitting device.

### 2. Description of Related Art

Japanese Unexamined Patent Application Publication No. H03-060186 describes a method of manufacturing a copper wiring ceramic board.

Japanese Unexamined Patent Application Publication No. 2009-117542 describes a circuit board including an Ni plating layer, an Au plating layer, a first intermediate plating layer, and a second intermediate plating layer.

### SUMMARY

On the other hand, it is necessary to further improve the performance of a wiring board. Therefore, it is necessary to provide a wiring board, a semiconductor device, a light emitting device, a method of manufacturing a wiring board, and a method of manufacturing a light emitting device capable of improving the performance.

Other problems and novel features will be apparent from the descriptions of this specification and accompanying drawings.

A wiring board according to one embodiment includes an insulating substrate, a base layer arranged on an upper surface of the insulating substrate, a first metal layer arranged on an upper surface of the base layer and containing a first metal, a second metal layer arranged on an upper surface of the first metal layer and containing a second metal less noble than the first metal, a third metal layer arranged on an upper surface and a side surface of the second metal layer and containing the first metal, and a fourth metal layer arranged on an upper surface and a side surface of the third metal layer and containing a third metal more noble than the first metal, and an entire surface of the second metal layer is covered with the first metal layer and the third metal layer.

A semiconductor device according to one embodiment includes the above-described wiring board and a semiconductor element arranged on the wiring board.

A light emitting device according to one embodiment includes the above-described wiring board and a light emitting element arranged on the wiring board.

A method of manufacturing a wiring board according to one embodiment includes preparing an insulating substrate having a base layer formed on its upper surface, forming a resist layer on an upper surface of the base layer, developing and exposing the resist layer such that at least a part of the base layer is exposed from the resist layer, forming a first metal layer containing a first metal on the upper surface of the base layer exposed from the resist layer, forming a second metal layer containing a second metal less noble than the first metal on an upper surface of the first metal layer, removing the resist layer after forming the second metal layer, removing the base layer after removing the resist layer, forming a third metal layer containing the first metal on an upper surface and a side surface of the second metal layer, and forming a fourth metal layer containing a third metal more noble than the first metal on an upper surface and a side surface of the third metal layer.

A method of manufacturing a light emitting device according to one embodiment includes preparing the wiring board, arranging a light emitting element on the insulating substrate, and arranging a reflective member on the upper surface of the insulating substrate, and the reflective member is arranged so as to be in contact with the fourth metal layer, the third metal layer, and the base layer in arranging the reflective member.

According to the embodiment above, it is possible to provide a wiring board, a semiconductor device, a light emitting device, a method of manufacturing a wiring board, and a method of manufacturing a light emitting device capable of improving the performance.

### BRIEF DESCRIPTION OF DRAWINGS

FIG. 1 is a cross-sectional view of a wiring board according to one embodiment.

FIG. 2 is a cross-sectional view of a wiring board according to a studied example.

FIG. 3 is a plan view of a wiring board according to another embodiment.

FIG. 4 is a cross-sectional view taken along the line IV-IV in FIG. 3.

FIG. 5 is a cross-sectional view of a semiconductor device according to one embodiment.

FIG. 6 is a cross-sectional view of a semiconductor device according to another embodiment.

FIG. 7 is a cross-sectional view of a light emitting device according to one embodiment.

FIG. 8 is a cross-sectional view illustrating a method of manufacturing a wiring board according to one embodiment.

FIG. 9 is a cross-sectional view illustrating the method of manufacturing the wiring board according to one embodiment.

FIG. 10 is a cross-sectional view illustrating the method of manufacturing the wiring board according to one embodiment.

FIG. 11 is a cross-sectional view illustrating the method of manufacturing the wiring board according to one embodiment.

FIG. 12 is a cross-sectional view illustrating the method of manufacturing the wiring board according to one embodiment.

FIG. 13 is a cross-sectional view illustrating the method of manufacturing the wiring board according to one embodiment.

FIG. 14 is a cross-sectional view illustrating the method of manufacturing the wiring board according to one embodiment.

FIG. 15 is a cross-sectional view illustrating the method of manufacturing the wiring board according to one embodiment.

FIG. 16 is a cross-sectional view illustrating the method of manufacturing the wiring board according to one embodiment.

### DETAILED DESCRIPTION OF THE INVENTION

In this application, the embodiment will be described in a plurality of separated sections or the like if necessary as a matter of convenience. However, unless otherwise specified, these are not mutually independent and irrelevant, but are respective parts of a single example regardless of the order of description, or one is a partial detail or a partial or overall modification of the other. Furthermore, repetitive description of similar parts will be omitted in principle. Furthermore, each component in the embodiment is not indispensable, except when otherwise specified, when it is theoretically limited to that number, or when it is clearly indispensable from the context.

Similarly, when a material, composition, or the like is described as “X made of A” in the description of the embodiment or the like, it does not exclude those containing elements other than A, except when otherwise specified or when it is clearly made of only A from the context. For example, regarding a component, it means “X containing A as a main component” or the like.

Furthermore, when a specific numerical value or quantity is mentioned, a numerical value larger than the specific numerical value or a numerical value smaller than the specific numerical value is also acceptable, except when otherwise specified, when it is theoretically limited to the value, or when it is clearly limited to the value from the context.

In addition, in each drawing of the embodiment, the same or similar parts are denoted by the same or similar symbols or reference characters, and descriptions will not be repeated in principle.

In addition, in the accompanying drawings, hatching or the like may be omitted even in cross sections if it would make the drawings more complicated or if the distinction from voids is clear. In relation to this, when it is clear from the description or the like, the background contour lines may be omitted even for the holes that are closed in plan view. Furthermore, even if the drawing is not a cross section, hatching or dot patterns may be applied in order to clearly indicate that it is not a void or to clearly indicate the boundary of regions.

### Wiring Board

First, a wiring board according to one embodiment will be described. FIG. 1 is a cross-sectional view of the wiring board according to one embodiment. As illustrated in FIG. 1, the wiring board 1 according to this embodiment includes an insulating substrate 10, a base layer 20, and a wiring layer 30. The wiring layer 30 includes a first metal layer 31, a second metal layer 32, a third metal layer 33, and a fourth metal layer 34. The wiring layer 30 of the wiring board 1 according to this embodiment further includes an intermediate layer 35.

### Insulating Substrate

The insulating substrate 10 supports the wiring layer 30. The insulating substrate 10 has an upper surface 10a and a lower surface 10b. In this embodiment, the insulating substrate 10 has a plate-like shape. The planar shape of the insulating substrate 10 is, for example, a circle, an ellipse, a polygon such as a quadrangle or a hexagon, or a polygon with rounded corners. The size of the insulating substrate 10 including the size and number of the wiring layer 30 to be arranged on the insulating substrate 10 can be adjusted as appropriate depending on the required performance.

The insulating substrate 10 is preferably made of an insulating material. Examples of the insulating material include ceramics such as aluminum oxide, aluminum nitride, silicon oxide, silicon nitride, and silicon carbide and resins such as phenol resin, epoxy resin, silicone resin, polyimide resin, BT resin, and polyphthalamide. When using a resin, an inorganic filler may be mixed into the resin as necessary. This improves the mechanical strength and reduces the thermal expansion coefficient. Examples of the inorganic filler include glass fiber, silicon oxide, titanium oxide, and aluminum oxide. A substrate in which a layer of an insulating material is formed on the surface of a metal member may be used as the insulating substrate 10.

### Base Layer

The base layer 20 is arranged on the upper surface 10a of the insulating substrate 10. The base layer 20 has an upper surface 20a and a lower surface 20b. The lower surface 20b of the base layer 20 is in contact with the upper surface 10a of the insulating substrate 10. The base layer 20 is a layer serving as a base of the wiring layer 30. The base layer 20 has a function as an adhesive layer when forming the wiring layer 30 on the insulating substrate 10. The base layer 20 may be a single layer such as a Ti layer, a Cu layer, an Au layer, or an Ru layer, a stacked layer containing these, or an alloy layer, and is preferably at least one selected from a stacked layer of a Ti layer and a Cu layer, a stacked layer of a Ti layer and an Au layer, a stacked layer of a Ti layer and an Ag layer, an alloy layer of Ti and Ni, an alloy layer of Ti and W, an alloy layer of Cu and Ni, an alloy layer of Ni and Cr, a stacked layer of a Ti layer and a TiNi layer, a stacked layer of a Ti layer and a TiW layer, a stacked layer of a Ti layer, a TiW layer, and a Cu layer, a stacked layer of a Ti layer, an Ru layer, and a Cu layer, and others. The TiNi alloy may contain a small amount of Ti relative to Ni, and the ratio of Ni and Ti is preferably about 93:7. Here, for example, the stacked layer of Ti and Cu is a layer in which a layer made of Ti and a layer made of Cu are stacked. Also, for example, the alloy layer of Ti and Ni is a layer made of an alloy of Ti and Ni. Also, the Ti layer is a layer made of Ti. The base layer 20 is preferably formed of a layer in which a plurality of layers made of at least one selected from a stacked layer of Ti and Cu, a stacked layer of Ti and Au, a stacked layer of Ti and Ag, an alloy layer of Ti and Ni, an alloy layer of Ti and W, an alloy layer of Cu and Ni, an alloy layer of Ni and Cr, and a Ti layer are stacked. The thickness of the base layer 20 is preferably 0.1 μm or more and 2.0 μm or less. The base layer 20 is preferably made of a Ti layer and an alloy layer of Ti and Ni. In this case, the Ti layer is preferably arranged on the side closer to the insulating substrate 10. Also, in this case, the thickness of the Ti layer is preferably 0.03 μm or more and 0.2 μm or less. Furthermore, in this case, the thickness of the alloy layer of Ti and Ni is preferably 0.2 μm or more and 1.5 μm or less. For example, the thickness of the Ti layer is 0.05 μm, and the thickness of the TiNi layer is 1.1 μm.

### Wiring Layer

The wiring layer 30 is arranged on the upper surface 20a of the base layer 20. The wiring layer 30 is a layer provided for efficient heat propagation as well as electrical conduction to the insulating substrate 10. As illustrated in FIG. 1, the wiring layer 30 is made up of a plurality of metal layers.

### First Metal Layer 31

The first metal layer 31 is arranged on the upper surface 20a of the base layer 20. The first metal layer 31 has an upper surface 31a, a lower surface 31b, and a side surface 31c. A part of the lower surface 31b of the first metal layer 31 is in contact with the upper surface 20a of the base layer 20. In the cross-sectional view illustrated in FIG. 1, the width of the first metal layer 31 is larger than the width of the base layer 20. The width of the lower surface 31b of the first metal layer 31 is larger than the width of the upper surface 20a of the base layer 20. Therefore, a part of the lower surface 31b of the first metal layer 31 is exposed. The thickness of the first metal layer 31 is preferably 1.0 μm or more and 5.0 μm or less.

When the upper surface 10a of the insulating substrate 10 is seen in plan view, a part of the edge of the upper surface 20a of the base layer 20 is located on the inner side relative to the edge of the lower surface 31b of the first metal layer 31. When the upper surface 10a of the insulating substrate 10 is seen in plan view, it is preferable that the entire edge of the upper surface 20a of the base layer 20 is located on the inner side relative to the edge of the lower surface 31b of the first metal layer 31. When the upper surface 10a of the insulating substrate 10 is seen in plan view, the edge of the base layer 20 is located on the inner side relative to the edge of the first metal layer 31. When the upper surface 10a of the insulating substrate 10 is seen in plan view, the distance from the edge of the upper surface 20a of the base layer 20 to the edge of the lower surface 31b of the first metal layer 31 is preferably 1.0 μm or more and 5.0 μm or less. At least a part of the first metal layer 31 is separated from the insulating substrate 10. It is preferable that the first metal layer 31 is not in contact with the insulating substrate 10.

The first metal layer 31 is made of a metal material. In this embodiment, the first metal layer 31 is made of a single first metal. The first metal is, for example, Ni.

### Second Metal Layer 32

The second metal layer 32 is arranged on the upper surface 31a of the first metal layer 31. The second metal layer 32 has an upper surface 32a, a lower surface 32b, and a side surface 32c. The lower surface 32b of the second metal layer 32 is in contact with the upper surface 31a of the first metal layer 31. When the upper surface 10a of the insulating substrate 10 is seen in plan view, the shape of the lower surface 32b of the second metal layer 32 is substantially the same as the shape of the upper surface 31a of the first metal layer 31. In the cross-sectional view illustrated in FIG. 1, the width of the second metal layer 32 is substantially the same as the width of the first metal layer 31. The width of the second metal layer 32 is larger than the width of the base layer 20. The width of the lower surface 32b of the second metal layer 32 is larger than the width of the upper surface 20a of the base layer 20. The thickness of the second metal layer 32 is preferably 5 μm or more and 60 μm or less. The thickness of the second metal layer 32 is, for example, 45 μm.

When the upper surface 10a of the insulating substrate 10 is seen in plan view, a part of the edge of the upper surface 20a of the base layer 20 is located on the inner side relative to the edge of the lower surface 32b of the second metal layer 32. When the upper surface 10a of the insulating substrate 10 is seen in plan view, it is preferable that the entire edge of the upper surface 20a of the base layer 20 is located on the inner side relative to the edge of the lower surface 32b of the second metal layer 32. When the upper surface 10a of the insulating substrate 10 is seen in plan view, the edge of the base layer 20 is located on the inner side relative to the edge of the second metal layer 32. When the upper surface 10a of the insulating substrate 10 is seen in plan view, the distance from the edge of the upper surface 20a of the base layer 20 to the edge of the lower surface 32b of the second metal layer 32 is preferably 1.0 μm or more and 5.0 μm or less.

The second metal layer 32 is made of a metal material. In this embodiment, the second metal layer 32 is made of a single second metal. The second metal has a standard electrode potential less noble than that of the first metal constituting the first metal layer 31. The second metal is, for example, Cu.

### Third Metal Layer 33

The third metal layer 33 is arranged on the upper surface 32a and the side surface 32c of the second metal layer 32. The third metal layer 33 has an upper surface 33a and a side surface 33c. The third metal layer 33 is in contact with the upper surface 32a and the side surface 32c of the second metal layer 32. The third metal layer 33 is arranged on the side surface 31c of the first metal layer 31. The third metal layer 33 is in contact with the side surface 31c of the first metal layer 31. The entire surface of the second metal layer 32 is covered with the first metal layer 31 and the third metal layer 33. The surface of the second metal layer 32 is in contact with the first metal layer 31 or the third metal layer 33. A part of the third metal layer 33 is separated from the insulating substrate 10. It is preferable that the third metal layer 33 is not in contact with the insulating substrate 10. The thickness of the third metal layer 33 is preferably 1.0 μm or more and 10.0 μm or less. The thickness of the third metal layer 33 arranged on the upper surface 32a of the second metal layer 32 is, for example, 2.0 μm or more and 10.0 μm or less.

The third metal layer 33 is made of a metal material. The third metal layer 33 is made of the first metal like the first metal layer 31.

### Intermediate Layer

The intermediate layer 35 is arranged on the upper surface 33a and the side surface 33c of the third metal layer 33. The intermediate layer 35 has an upper surface 35a and a side surface 35c. The intermediate layer 35 is in contact with the upper surface 33a and the side surface 33c of the third metal layer 33. The intermediate layer 35 prevents the metal contained in the third metal layer 33 from diffusing into the fourth metal layer 34. Since the intermediate layer 35 is not indispensable, there are cases where the intermediate layer 35 is not provided. A part of the intermediate layer 35 is separated from the insulating substrate 10. It is preferable that the intermediate layer 35 is not in contact with the insulating substrate 10. The thickness of the intermediate layer 35 is preferably 0.05 μm or more and 0.2 μm or less. The thickness of the intermediate layer 35 is, for example, 0.1 μm.

The intermediate layer 35 is made of a metal material. In this embodiment, the intermediate layer 35 is made of a single fourth metal. It is preferable that the fourth metal is a metal that prevents the first metal from diffusing into the fourth metal layer 34. The fourth metal is, for example, Pd.

### Fourth Metal Layer 34

The fourth metal layer 34 is arranged on the upper surface 35a and the side surface 35c of the intermediate layer 35. The fourth metal layer 34 has an upper surface 34a and a side surface 34c. The fourth metal layer 34 is in contact with the upper surface 35a and the side surface 35c of the intermediate layer 35. However, when the intermediate layer 35 is not provided, the fourth metal layer 34 is arranged on the upper surface 33a and the side surface 33c of the third metal layer 33. Also, when the intermediate layer 35 is not provided, the fourth metal layer 34 is in contact with the upper surface 33a and the side surface 33c of the third metal layer 33. A part of the fourth metal layer 34 is separated from the insulating substrate 10. It is preferable that the fourth metal layer 34 is not in contact with the insulating substrate 10. The thickness of the fourth metal layer 34 is preferably 0.05 μm or more and 0.2 μm or less. The thickness of the fourth metal layer 34 is, for example, 0.1 μm.

The fourth metal layer 34 is made of a metal material. In this embodiment, the fourth metal layer 34 is made of a single third metal. It is preferable that the third metal does not alloy with the first metal and the fourth metal. The third metal has a standard electrode potential more noble than that of the first metal constituting the first metal layer 31 and the second metal constituting the second metal layer 32. The third metal is, for example, Au.

Next, the configuration and effects of the wiring board 1 according to this embodiment will be described. As illustrated in FIG. 1, the width of the wiring layer 30 in one direction is larger than the width of the base layer 20 in the same direction. In addition, the wiring layer 30 is separated from the insulating substrate 10. More specifically, a gap Nl is formed between the wiring layer 30 and the insulating substrate 10. As a result, the side surface 20c of the base layer 20 is exposed. In addition, a part of the first metal layer 31, a part of the third metal layer 33, and a part of the intermediate layer 35 are exposed. On the other hand, the second metal layer 32 of the wiring layer 30 is covered with the first metal layer 31 and the third metal layer 33. Therefore, the second metal layer 32 of the wiring layer 30 is not exposed.

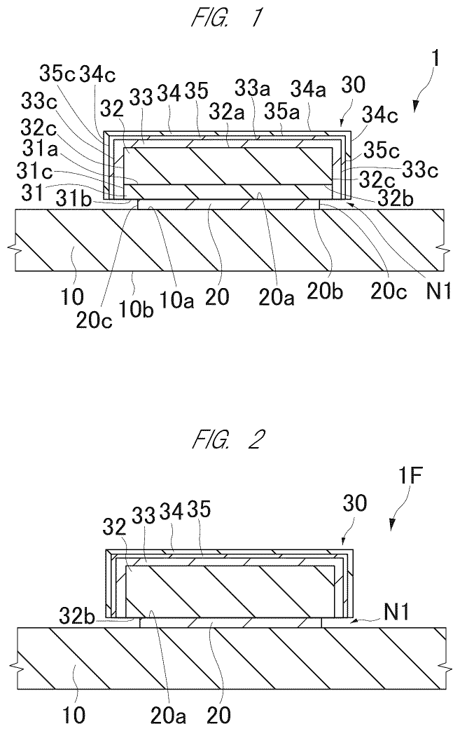

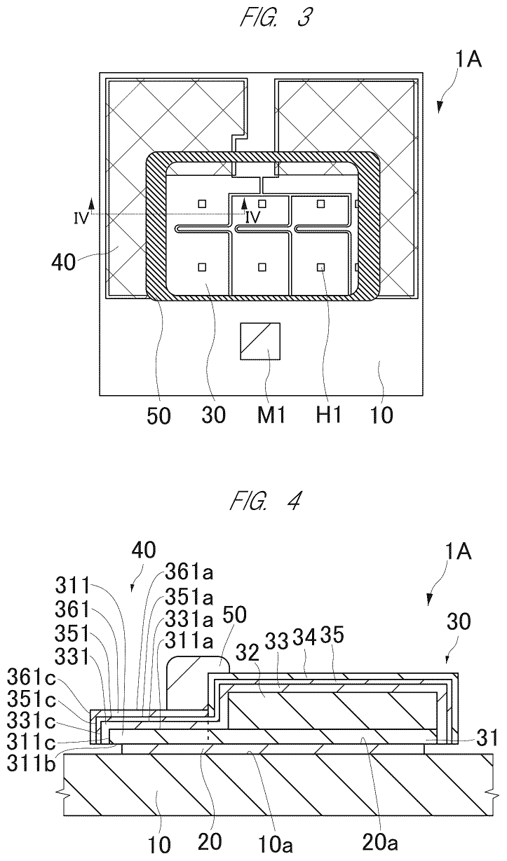

FIG. 2 is a cross-sectional view of a wiring board according to a studied example. As illustrated in FIG. 2, the second metal layer 32 of the wiring board 1F is arranged on the upper surface of the base layer 20. More specifically, a layer corresponding to the first metal layer 31 of the wiring board 1 is not formed in the wiring board 1F. Except that the layer corresponding to the first metal layer 31 is not formed, the cross-sectional structure of the wiring board 1F is the same as that of the wiring board 1.

When arranging the wiring layer 30 on the insulating substrate 10, the base layer 20 is arranged in some cases between the insulating substrate 10 and the wiring layer 30 for reasons such as improving the adhesion between the wiring layer 30 and the insulating substrate 10. However, when arranging the base layer 20 between the insulating substrate 10 and the wiring layer 30, a part or all of the wiring layer 30 is first formed on the base layer 20, and then the excess base layer 20 is removed by etching in order to prevent short-circuits. On the other hand, as illustrated in FIG. 2, when removing the base layer 20 by etching, there is a possibility that the base layer 20 is over-etched. This may cause the width of the base layer 20 to be smaller than the width of the wiring layer 30. As a result, the gap N1 is formed between the wiring layer 30 and the insulating substrate 10. Here, the case where the second metal layer 32 made of the second metal which is prone to corrosion and is relatively noble is arranged on the base layer 20 in order to reduce the amount of use of the third metal whose standard electrode potential is relatively noble will be studied. As described above, when the width of the base layer 20 is smaller than the width of the wiring layer 30, there is a possibility that the edge of the upper surface 20a of the base layer 20 is located on the inner side relative to the edge of the lower surface 32b of the second metal layer 32 when the insulating substrate 10 is seen in plan view. This may cause the lower surface 32b of the second metal layer 32 which is prone to corrosion to be exposed from the gap N1. When the lower surface 32b of the second metal layer 32 is exposed from the gap N1, there is a high possibility that the corrosion occurs when it comes into contact with, for example, water, salt water, oxygen, or a gas containing sulfur. As a result, in the wiring board 1F illustrated in FIG. 2, there is a high possibility that the current density increases locally due to corrosion and the disconnection occurs depending on the current flowing through the wiring layer 30.

As illustrated in FIG. 1, in this embodiment, the fourth metal layer 34 made of the third metal whose standard electrode potential is relatively noble is arranged so as to be exposed from the outer surface of the wiring layer 30. Also, the second metal layer 32 made of the second metal which is less noble than the third metal is arranged inside the wiring layer 30 so as not to be exposed from the outer surface of the wiring layer 30. This makes it possible to reduce the amount of use of the third metal whose standard electrode potential is relatively noble.

In addition, in the wiring board 1 according to this embodiment, the entire circumference of the second metal layer 32 made of the second metal is covered with the first metal layer 31 and the third metal layer 33 made of the first metal whose standard electrode potential is more noble than that of the second metal. This makes it possible to prevent the second metal layer 32 made of the second metal which is prone to corrosion and is relatively less noble from being exposed. As a result, the wiring layer 30 becomes less susceptible to corrosion. Therefore, even if the amount of use of the third metal whose standard electrode potential is relatively noble is reduced, it is possible to provide the wiring board 1 that is less susceptible to corrosion.

Furthermore, in the wiring board 1 according to this embodiment, the entire circumference of the second metal layer 32 made of the second metal is covered with the first metal layer 31 and the third metal layer 33 made of the first metal whose standard electrode potential is more noble than that of the second metal. This makes it possible to prevent the second metal layer 32 from being exposed even in the case where the edge of the upper surface 20a of the base layer 20 is located on the inner side relative to the edge of the lower surface 32b of the second metal layer 32 when the insulating substrate 10 is seen in plan view. As a result, even if the amount of use of the third metal whose standard electrode potential is relatively noble is reduced, it is possible to provide the wiring board 1 that is still less susceptible to corrosion.

### Modification

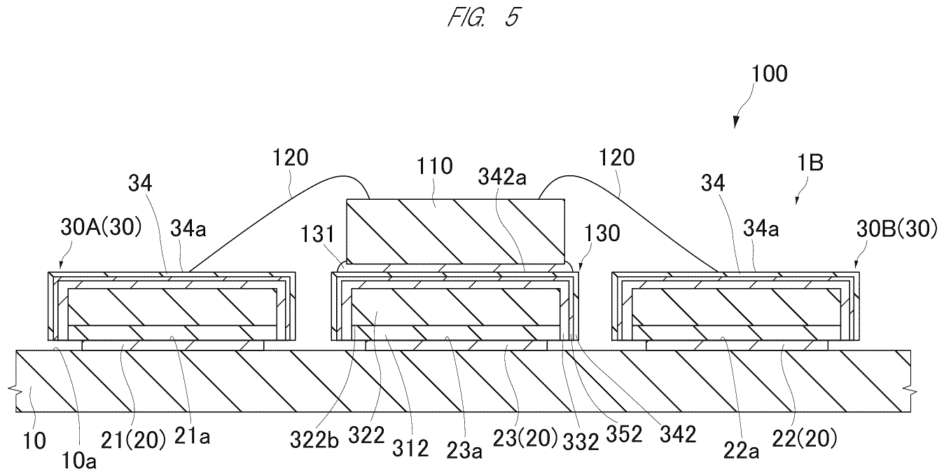

FIG. 3 is a plan view of a wiring board according to another embodiment. FIG. 4 is a cross-sectional view taken along the line IV-IV in FIG. 3. As illustrated in FIG. 3, the wiring board 1A according to another embodiment further includes a pad portion 40, a light reflecting layer 50, a recognition mark M1, and a hole H1. The pad portion 40 is electrically connected to the wiring layer 30. As illustrated in FIG. 4, the pad portion 40 is electrically connected to the fourth metal layer 34 of the wiring layer 30. The pad portion 40 includes a first metal layer 311, a third metal layer 331, an intermediate layer 351, and a fifth metal layer 361. The fifth metal layer 361 is electrically connected to the fourth metal layer 34 of the wiring layer 30.

As illustrated in FIG. 4, the pad portion 40 is provided on the upper surface 20a of the base layer 20. In other words, the pad portion 40 and the wiring layer 30 are provided on the same upper surface 20a of the base layer 20.

The first metal layer 311 of the pad portion 40 is provided on the upper surface 20a of the base layer 20. A lower surface 311b of the first metal layer 311 is in contact with the upper surface 20a of the base layer 20. The first metal layer 311 of the pad portion 40 is provided integrally with the first metal layer 31 of the wiring layer 30. In the example illustrated in FIG. 4, the first metal layer 311 of the pad portion 40 and the first metal layer 31 of the wiring layer 30 are connected at the portion indicated by the dotted line. The material of the first metal layer 311 is preferably the same as the material of the first metal layer 31. Since the first metal layer 311 is not indispensable, there are cases where the first metal layer 311 is not provided. When the upper surface 10a of the insulating substrate 10 is seen in plan view, a part of the edge of the upper surface 20a of the base layer 20 is located on the inner side relative to the edge of the lower surface 311b of the first metal layer 311. The third metal layer 331 of the pad portion 40 is provided on an upper surface 311a and a side surface 311c of the first metal layer 311. The third metal layer 331 of the pad portion 40 is provided integrally with the third metal layer 33 of the wiring layer 30. In the example illustrated in FIG. 4, the third metal layer 331 of the pad portion 40 and the third metal layer 33 of the wiring layer 30 are connected at the portion indicated by the dotted line. The material of the third metal layer 331 is preferably the same as the material of the third metal layer 33. Since the third metal layer 331 is not indispensable, there are cases where the third metal layer 331 is not provided.

The intermediate layer 351 is provided on an upper surface 331a and a side surface 331c of the third metal layer 331. The intermediate layer 351 of the pad portion 40 is provided integrally with the intermediate layer 35 of the wiring layer 30. In the example illustrated in FIG. 4, the intermediate layer 351 of the pad portion 40 and the intermediate layer 35 of the wiring layer 30 are connected at the portion indicated by the dotted line. The material of the intermediate layer 351 is preferably the same as the material of the intermediate layer 35. Since the intermediate layer 351 is not indispensable, there are cases where the intermediate layer 351 is not provided. The fifth metal layer 361 is provided on an upper surface 351a and a side surface 351c of the intermediate layer 351. The fifth metal layer 361 is preferably made of a fifth metal whose standard electrode potential is less noble than that of the third metal of the fourth metal layer 34. The fifth metal is, for example, Al.

As illustrated in FIG. 4, a layer corresponding to the second metal layer 32 made of the second metal is not provided in the pad portion 40. In addition, instead of the fifth metal layer 361 of the pad portion 40, a fourth metal layer 341 made of the third metal may be provided. When the fourth metal layer 341 is provided, the fourth metal layer 341 of the pad portion 40 is provided integrally with the fourth metal layer 34 of the wiring layer 30.

For example, an external power supply member is electrically connected to the pad portion 40. An electronic component may be arranged on the fourth metal layer 34 of the wiring layer 30. The terminal of the electronic component is electrically connected to, for example, the fourth metal layer 34. The fifth metal layer 361 of the pad portion 40 is electrically connected to, for example, the terminal of the electronic component via the fourth metal layer 34 of the wiring layer 30. The fifth metal layer 361 of the pad portion 40 is not directly connected to the terminal of the electronic component. In other words, the second metal layer 32 made of the second metal is provided at the portion directly connected to the terminal of the electronic component. On the other hand, the second metal layer 32 made of the second metal may not be provided at the portion not directly connected to the terminal of the electronic component.

Examples of the electronic component include two-terminal devices such as a semiconductor light emitting element, a power semiconductor, a power supply rectifier diode, a Zener diode, a variable capacitance diode, a PIN diode, a Schottky barrier diode, a photodiode, a solar cell, a surge protection diode, a varistor, a capacitor, and a resistor, three-terminal devices such as a transistor, a bipolar transistor, a field effect transistor, a phototransistor, a CCD image sensor, a thyristor, and a light-triggered thyristor, memories such as a DRAM and an SRAM, and microprocessors.

As illustrated in FIG. 4, the light reflecting layer 50 covers the fourth metal layer 34. It is preferable that the total light reflectance of the light reflecting layer 50 when irradiated with light of 450 nm or more and 460 nm or less is higher than the total light reflectance of the fourth metal layer 34. It is also preferable that the total light reflectance of the light reflecting layer 50 when irradiated with light of 430 nm is 70% or more. The total light reflectance includes diffuse reflection and specular reflection.

The light reflecting layer 50 is, for example, a silicone resin, a modified silicone resin, an epoxy resin, a modified epoxy resin, an acrylic resin, or a hybrid resin containing at least one of these resins. The light reflecting layer 50 preferably further contains a filler such as a light reflecting material. Examples of the light reflecting material include titanium oxide, silicon oxide, zirconium oxide, potassium titanate, aluminum oxide, aluminum nitride, boron nitride, and mullite.

As illustrated in FIG. 3, the recognition mark M1 is provided on the upper surface 10a of the insulating substrate 10. The recognition mark M1 is provided so as to be separated from the wiring layer 30. The recognition mark M1 can be used for position recognition of electronic components when the wiring board 1A on which the electronic components are mounted is secondarily mounted, position recognition when a resin frame is formed in the manufacturing process, and others. The recognition mark M1 can be formed using the same metal material as the wiring layer 30. The surface of the recognition mark M1 is preferably formed using the same metal material as the fourth metal layer 34. By using the same metal material for the recognition mark M1 and the surface of the wiring layer 30, it is possible to suppress corrosion of the metal due to the potential difference between the different metal materials.

As illustrated in FIG. 3, the hole Hl is provided in the wiring layer 30. It is preferable that the insulating substrate 10 is exposed from the hole H1. For example, the hole H1 can hold a frame body when the frame body is attached to the wiring board 1A. This can improve the adhesion between the frame body and the insulating substrate 10.

### Semiconductor Device

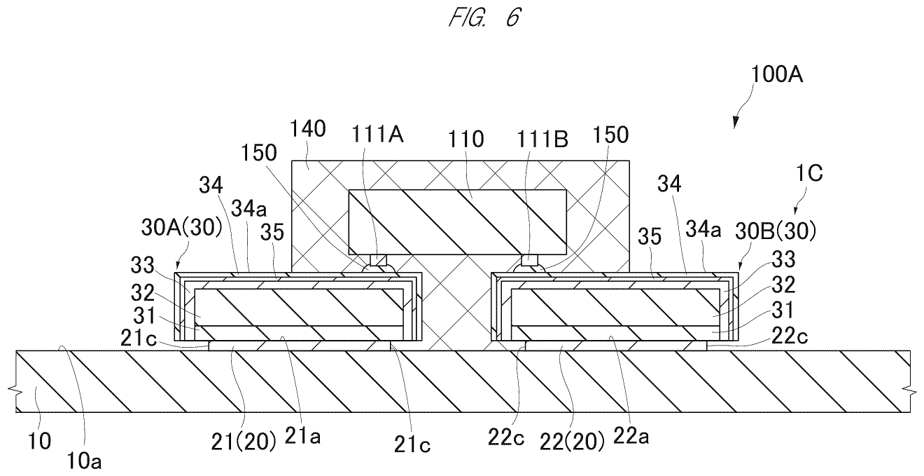

Next, the semiconductor device according to this embodiment will be described. FIG. 5 is a cross-sectional view of the semiconductor device according to this embodiment. As illustrated in FIG. 5, the semiconductor device 100 according to this embodiment includes a wiring board 1B, a semiconductor element 110, a wire 120, and a die pad 130.

### Wiring Board

The wiring board 1B includes the insulating substrate 10, a plurality of base layers 20, and a plurality of wiring layers 30.

As illustrated in FIG. 5, the plurality of base layers 20 include a base layer 21, a base layer 22, and a base layer 23. In the cross-sectional view illustrated in FIG. 5, the base layer 21, the base layer 22, and the base layer 23 are separated from each other. Moreover, the base layer 23 is arranged between the base layer 21 and the base layer 22. The plurality of wiring layers 30 include a wiring layer 30A and a wiring layer 30B. The wiring layer 30A is arranged on an upper surface 21a of the base layer 21. The wiring layer 30B is arranged on an upper surface 22a of the base layer 22. In the example illustrated in FIG. 5, the cross-sectional structures of the wiring layer 30A and the wiring layer 30B are the same. Also, the cross-sectional structures of the wiring layer 30A and the wiring layer 30B are the same as the cross-sectional structure of the wiring layer 30 illustrated in FIG. 1. A die pad 130 is arranged on an upper surface 23a of the base layer 23.

### Die Pad

As illustrated in FIG. 5, the cross-sectional structure of the die pad 130 is the same as the cross-sectional structure of the wiring layer 30 illustrated in FIG. 1. As illustrated in FIG. 5, the die pad 130 is arranged between the wiring layer 30A and the wiring layer 30B, and is separated from the wiring layer 30A and the wiring layer 30B. The die pad 130 is provided on the upper surface 23a of the base layer 23. The die pad 130 supports the semiconductor element 110.

The die pad 130 includes a first metal layer 312, a second metal layer 322, a third metal layer 332, a fourth metal layer 342, and an intermediate layer 352. The material and shape of the first metal layer 312 are preferably the same as the material and shape of the first metal layer 31 illustrated in FIG. 1. The material and shape of the second metal layer 322 are preferably the same as the material and shape of the second metal layer 32 illustrated in FIG. 1. The material and shape of the third metal layer 332 are preferably the same as the material and shape of the third metal layer 33 illustrated in FIG. 1. The material and shape of the fourth metal layer 342 are preferably the same as the material and shape of the fourth metal layer 34 illustrated in FIG. 1. The material and shape of the intermediate layer 352 are preferably the same as the material and shape of the intermediate layer 35 illustrated in FIG. 1.

### Semiconductor Element

As illustrated in FIG. 5, the semiconductor element 110 is provided on the die pad 130. The semiconductor element 110 is provided on an upper surface 342a of the fourth metal layer 342 of the die pad 130 via an adhesive layer 131. The semiconductor element 110 is fixed on the upper surface 342a of the fourth metal layer 342 of the die pad 130 by the adhesive layer 131. The semiconductor element 110 has, for example, a plurality of terminals.

### Wire

As illustrated in FIG. 5, a plurality of wires 120 are provided. The semiconductor element 110 and the wiring layer 30A are electrically connected by the wire 120. The fourth metal layer 34 of the wiring layer 30A is in contact with one end of the wire 120. One terminal of the semiconductor element 110 is in contact with the other end of the wire 120. The semiconductor element 110 and the wiring layer 30B are electrically connected by the wire 120. The fourth metal layer 34 of the wiring layer 30B is in contact with one end of the wire 120. Another terminal of the semiconductor element 110 is in contact with the other end of the wire 120.

Next, the effects of the semiconductor device 100 will be described. As illustrated in FIG. 5, the cross-sectional structure of the die pad 130 is the same as that of the wiring layer 30 illustrated in FIG. 1. More specifically, the entire outer surface of the second metal layer 322 made of the second metal is covered with the first metal layer 312 and the third metal layer 332 made of the first metal whose standard electrode potential is more noble than that of the second metal. In this way, the second metal layer 322 is not exposed even in the case where the edge of the upper surface 23a of the base layer 23 is located on the inner side relative to the edge of the lower surface 322b of the second metal layer 322 when the insulating substrate 10 is seen in plan view. This makes the die pad 130 less susceptible to corrosion. As a result, the semiconductor device 100 is made less susceptible to corrosion. Therefore, it is possible to improve the environmental resistance of the semiconductor device 100 while reducing the amount of use of noble metal.

In addition, the semiconductor element 110 serves as a heat source, but even when a material whose thermal conductivity is low is used for the insulating substrate 10, the thermal conductivity of the insulating substrate 10 can be compensated by increasing the amount of use of the less noble second metal whose thermal conductivity is high, so that the thermal conductivity of the wiring board 1 can be increased. As a result, the heat generated from the semiconductor element 110 can be efficiently dissipated and the characteristics thereof can be maintained for a long period of time.

### Modification

FIG. 6 is a cross-sectional view of a semiconductor device according to another embodiment. As illustrated in FIG. 6, the semiconductor device 100A according to this embodiment includes a wiring board 1C, the semiconductor element 110, and a sealing body 140.

### Wiring Board

The wiring board 1C includes the insulating substrate 10, the plurality of base layers 20, and the plurality of wiring layers 30.

As illustrated in FIG. 6, the plurality of base layers 20 include the base layer 21 and the base layer 22. In the cross-sectional view illustrated in FIG. 6, the base layers 21 and 22 are arranged so as to be separated from each other. The plurality of wiring layers 30 include the wiring layer 30A and the wiring layer 30B. The wiring layer 30A is arranged on the upper surface 21a of the base layer 21. The wiring layer 30B is arranged on the upper surface 22a of the base layer 22. In the example illustrated in FIG. 6, the cross-sectional structures of the wiring layers 30A and 30B are the same. Also, the cross-sectional structures of the wiring layers 30A and 30B are the same as the cross-sectional structure of the wiring layer 30 illustrated in FIG. 1.

### Semiconductor Element

As illustrated in FIG. 6, the semiconductor element 110 has an electrode 111A and an electrode 111B. The electrode 111A and the electrode 111B are, for example, columnar electrodes formed on the semiconductor element 110. The electrode 111A of the semiconductor element 110 is connected to the upper surface 34a of the fourth metal layer 34 of the wiring layer 30A. In the example illustrated in FIG. 6, the electrode 111A is electrically connected to the fourth metal layer 34 of the wiring layer 30A via a conductive material 150. The electrode 111B of the semiconductor element 110 is connected to the upper surface 34a of the fourth metal layer 34 of the wiring layer 30B. In the example illustrated in FIG. 6, the electrode 111B is electrically connected to the fourth metal layer 34 of the wiring layer 30B via a conductive material 150. The conductive material 150 is, for example, solder.

### Sealing Body

The sealing body 140 is provided on the upper surface 10a of the insulating substrate 10 of the wiring board 1C. The semiconductor element 110 is sealed by the sealing body 140. The conductive material 150 is sealed by the sealing body 140. A part of the base layer 21 and a part of the base layer 22 are sealed by the sealing body 140. A part of the side surface 21c of the base layer 21 and a part of the side surface 22c of the base layer 22 are exposed from the sealing body 140. A part of the wiring layer 30A and a part of the wiring layer 30B are sealed by the sealing body 140. A part of the first metal layer 31 of the wiring layer 30A, a part of the third metal layer 33 of the wiring layer 30A, a part of the fourth metal layer 34 of the wiring layer 30A, and a part of the intermediate layer 35 of the wiring layer 30A are exposed from the sealing body 140. A part of the first metal layer 31 of the wiring layer 30B, a part of the third metal layer 33 of the wiring layer 30B, a part of the fourth metal layer 34 of the wiring layer 30B, and a part of the intermediate layer 35 of the wiring layer 30B are exposed from the sealing body 140.

The sealing body 140 is made of, for example, a resin material. It is preferable that the sealing body 140 has insulating properties. Examples of the resin material include thermosetting resins and the like. It is preferable that the sealing body 140 further contains a filler.

Next, the effects of the semiconductor device 100A will be described. As illustrated in FIG. 6, the cross-sectional structure of the wiring layer 30A and the cross-sectional structure of the wiring layer 30B are the same as the cross-sectional structure of the wiring layer 30 illustrated in FIG. 1. In this way, even when a part of the wiring layer 30A and the wiring layer 30B is exposed from the sealing body 140, it is possible to prevent the second metal layer 32 of the wiring layer 30A and the second metal layer 32 of the wiring layer 30B from being exposed from the outer surface of the semiconductor device 100A. Therefore, even if the wiring layer 30A and the wiring layer 30B are not entirely sealed with the sealing body 140, it is possible to prevent the corrosion of the wiring layer 30A and the wiring layer 30B. As a result, the semiconductor device 100A is made less susceptible to corrosion. Therefore, it is possible to improve the environmental resistance of the semiconductor device 100A while reducing the amount of use of noble metal.

In addition, the semiconductor element 110 serves as a heat source, but even when a material whose thermal conductivity is low is used for the insulating substrate 10, the thermal conductivity of the insulating substrate 10 can be compensated by increasing the amount of use of the less noble second metal whose thermal conductivity is high, so that the thermal conductivity of the wiring board 1 can be increased. As a result, the heat generated from the semiconductor element 110 can be efficiently dissipated and the characteristics thereof can be maintained for a long period of time.

### Light Emitting Device

Next, a light emitting device according to this embodiment will be

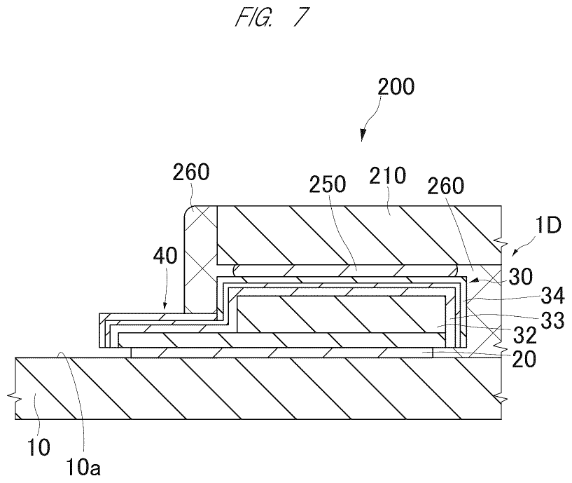

described. FIG. 7 is a cross-sectional view of the light emitting device according to one embodiment. As illustrated in FIG. 7, the light emitting device 200 according to this embodiment includes a wiring board 1D, a light emitting element 210, a conductive material 250, and a reflective member 260.

### Wiring Board

The wiring board 1D includes the insulating substrate 10, the base layer 20, the wiring layer 30, and the pad portion 40. The configurations of the insulating substrate 10, the base layer 20, the wiring layer 30, and the pad portion 40 of the wiring board 1D are the same as those of the wiring board 1A illustrated in FIG. 4.

### Light Emitting Element

The light emitting element 210 is connected to the wiring layer 30 of the wiring board 1D via the conductive material 250. The light emitting element 210 has, for example, a terminal. The terminal of the light emitting element 210 is electrically connected to, for example, the fourth metal layer 34 of the wiring layer 30 via the conductive material 250.

The light emitting element 210 is, for example, a light emitting diode. Examples of the light emitting diode include light emitting diodes using nitride-based semiconductor, GaAlAs, and AlInGaP. The light emitting element 210 has, for example, a plurality of terminals. For example, the light emitting element 210 preferably has a pair of positive and negative terminals on the same surface. This allows the light emitting element 210 to be flip-chip mounted on a mounting board. In this case, the surface of the light emitting element 210 opposite to the surface of the light emitting element 210 on which the pair of terminals are formed serves as the main light extraction surface. The outermost surface of the terminal of the light emitting element 210 is preferably made of gold. Gold is chemically stable, and thus can ensure the reliability of the electrical connection.

### Conductive Material

The conductive material 250 can bond the wiring layer 30 and the light emitting element 210. Examples of the conductive material 250 include tin-bismuth, tin-copper, tin-silver, and gold-tin solders, eutectic alloys such as alloy mainly containing Au and Sn, alloy mainly containing Au and Si, and alloy mainly containing Au and Ge, conductive pastes of silver, gold, palladium, or the like, bumps, anisotropic conductive materials such as ACP (Anisotropic Conductive Paste) and ACF (Anisotropic Conductive Film), a brazing material made of a low melting point metal, and conductive adhesives and conductive composite adhesives obtained by combining these.

### Reflective Member

The reflective member 260 is arranged on the upper surface 10a of the insulating substrate 10. The reflective member 260 is in contact with the fourth metal layer 34, the third metal layer 33, and the base layer 20. The reflective member 260 is preferably formed of a material capable of reflecting the light emitted from the light emitting element 210. This allows the light emitted from the light emitting element 210 to be reflected into the light emitting element 210 at the interface between the light emitting element 210 and the reflective member 260. As a result, the light propagates in the light emitting element 210 and is finally emitted from the light emitting element to the outside. The reflective member 260 can further protect the light emitting element 210 from external forces, dust, gas, and the like.

The reflective member 260 is, for example, a silicone resin, a modified silicone resin, an epoxy resin, a modified epoxy resin, an acrylic resin, or a hybrid resin containing at least one of these resins. The reflective member 260 preferably further contains a filler such as a light reflecting material. Examples of the light reflecting material include titanium oxide, silicon oxide, zirconium oxide, potassium titanate, aluminum oxide, aluminum nitride, boron nitride, and mullite.

Next, the effects of the light emitting device 200 will be described. As illustrated in FIG. 7, the cross-sectional structure of the wiring layer 30 of the light emitting device 200 is the same as that of the wiring layer 30 illustrated in FIG. 4. This prevents the second metal layer 32 of the wiring layer 30 from being exposed from the outer surface of the light emitting device 200. As a result, the light emitting device 200 is made less susceptible to corrosion. Therefore, it is possible to improve the performance of the light emitting device 200. In this embodiment, the reflective member 260 is in contact with the fourth metal layer 34, the third metal layer 33, and the base layer 20. In other words, the reflective member 260 penetrates into the gap between the wiring layer 30 and the insulating substrate 10. This prevents the reflective member 260 from floating up to be peeled off.

### Method of Manufacturing Wiring Board

Next, a method of manufacturing a wiring board according to this embodiment will be described. FIG. 8 to FIG. 16 are cross-sectional views illustrating the method of manufacturing the wiring board according to this embodiment. The method of manufacturing the wiring board according to this embodiment includes the following steps.

S1: Preparing the insulating substrate 10 having the base layer 20 formed on its upper surface

S2: Forming a resist layer 70 on the upper surface of the base layer 20

S3: Exposing and developing the resist layer 70 such that at least a part of the base layer 20 is exposed from the resist layer 70

S4: Forming the first metal layer 31 on the upper surface of the base layer 20 exposed from the resist layer 70

S5: Forming the second metal layer 32 on the upper surface of the first metal layer 31

S6: Removing the resist layer 70 and the base layer 20 after forming the second metal layer 32

S7: Forming the third metal layer 33 on the upper surface and the side surface of the second metal layer 32

S8: Forming the intermediate layer 35 on the upper surface and the side surface of the third metal layer 33

S9: Forming the fourth metal layer 34 on the upper surface and the side surface of the intermediate layer 35

### Preparing Insulating Substrate 10 Having Base Layer 20 Formed on its Upper Surface

As illustrated in FIG. 8, in step S1, the insulating substrate 10 having the base layer 20 formed on its upper surface 10a is prepared.

The base layer 20 is arranged on the upper surface 10a of the insulating substrate 10. The lower surface 20b of the base layer 20 is in contact with the upper surface 10a of the insulating substrate 10. The base layer 20 is formed on the upper surface 10a of the insulating substrate 10 by, for example, sputtering.

### Forming Resist Layer 70 on Upper Surface of Base Layer 20

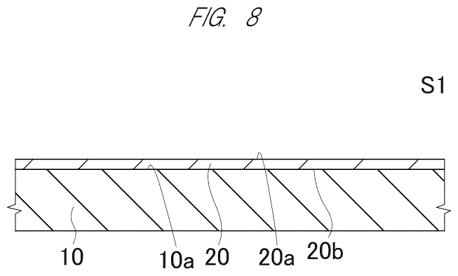

As illustrated in FIG. 9, in step S2, the resist layer 70 is formed on the upper surface 20a of the base layer 20 prepared in step S1. The resist layer 70 is formed such that the upper surface 20a of the base layer 20 is in contact with a lower surface 70b of the resist layer 70. The resist layer 70 is formed by, for example, applying a resin composition onto the upper surface 20a of the base layer 20. It is preferable that the thickness of the resist layer 70 is larger than the total thickness of the first metal layer 31 and the second metal layer 32. The resist layer 70 is made of, for example, a photosensitive resin composition containing a photosensitive resin. The photosensitive resin is, for example, a polyimide resin.

Exposing and Developing Resist Layer 70 Such That At Least Part of Base Layer 20 is Exposed from Resist Layer 70

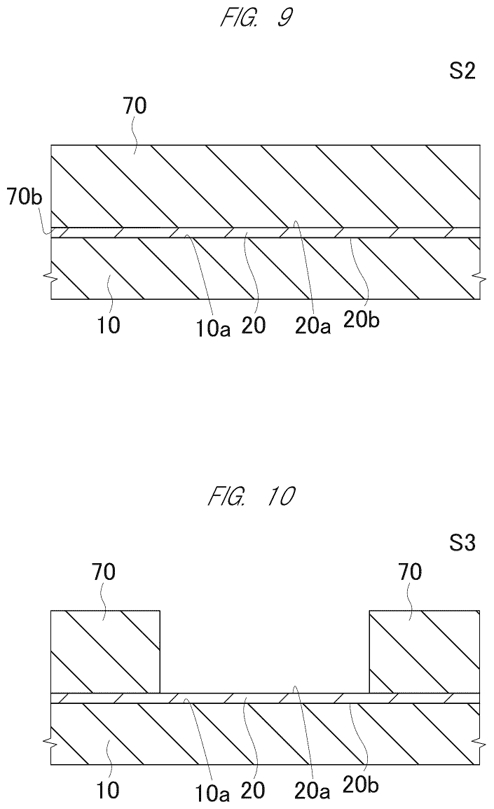

As illustrated in FIG. 10, in step S3, a part of the resist layer 70 formed in step S2 is removed such that a part of the base layer 20 is exposed. In the example illustrated in FIG. 10, a part of the upper surface 20a of the base layer 20 is exposed. The part of the resist layer 70 is removed by exposure and development. For example, the exposure method is to irradiate the part of the resist layer 70 formed in step S2 with ultraviolet light. For example, the development method is to develop the exposed resist layer 70 with a developer. The developer is made of, for example, an alkaline component and water.

Forming First Metal Layer 31 on Upper Surface of Base Layer 20 Exposed from Resist Layer 70

As illustrated in FIG. 11, in step S4, the first metal layer 31 is formed on the upper surface 20a of the base layer 20 exposed in step S3. The first metal layer 31 is formed by, for example, electrolytic plating or electroless plating. The lower surface 31b of the first metal layer 31 is in contact with the upper surface 20a of the base layer 20. The side surface 31c of the first metal layer 31 is in contact with the resist layer 70.

### Forming Second Metal Layer 32 on Upper Surface of First Metal Layer 31

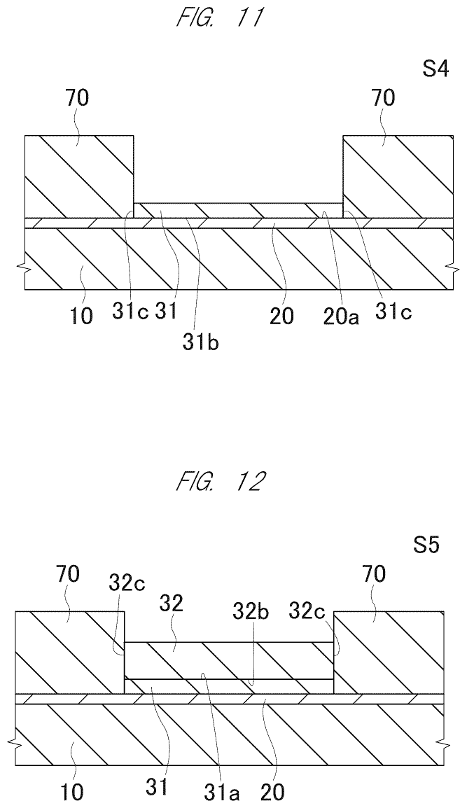

As illustrated in FIG. 12, in step S5, the second metal layer 32 is formed on the upper surface 31a of the first metal layer 31 formed in step S4. The second metal layer 32 is formed by, for example, electrolytic plating. The lower surface 32b of the second metal layer 32 is in contact with the upper surface 31a of the first metal layer 31. The side surface 32c of the second metal layer 32 is in contact with the resist layer 70.

### Removing Resist Layer 70 and Base Layer 20 After Forming Second Metal Layer 32

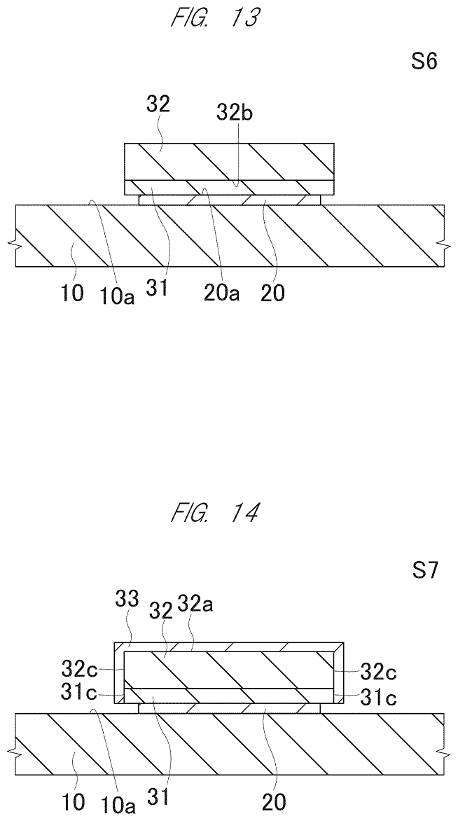

As illustrated in FIG. 13, in step S6, the resist layer 70 and the base layer 20 are removed after forming the second metal layer 32.

In this embodiment, the resist layer 70 is first removed after forming the second metal layer 32. The resist layer 70 is removed by, for example, etching. It is preferable that all of the resist layer 70 is removed in step S6.

In this embodiment, the base layer 20 is removed after removing the resist layer 70. The base layer 20 is removed by, for example, etching. In this case, since the first metal layer 31 and the second metal layer 32 serve as an etching mask, when the upper surface 10a of the insulating substrate 10 is seen in plan view, the etching effect reaches the base layer 20 located on the inner side relative to the edge of the second metal layer 32, and the edge of the base layer 20 is formed on the inner side relative to the edge of the second metal layer 32. It is preferable that the base layer 20 is removed such that the distance from the edge of the upper surface 20a of the base layer 20 to the edge of the lower surface 32b of the second metal layer 32 is 1.0 μm or more and 20.0 μm or less.

### Forming Third Metal Layer 33 on Upper Surface and Side Surface of Second Metal Layer 32

As illustrated in FIG. 14, in step S7, the third metal layer 33 is formed on the upper surface 32a and the side surface 32c of the second metal layer 32. The third metal layer 33 is in contact with the upper surface 32a and the side surface 32c of the second metal layer 32. The third metal layer 33 is formed by, for example, electroless plating. In the example illustrated in FIG. 14, the third metal layer 33 is formed also on the side surface 31c of the first metal layer 31. The third metal layer 33 is in contact with the side surface 31c of the first metal layer 31.

### Forming Intermediate Layer 35 on Upper Surface and Side Surface of Third Metal Layer 33

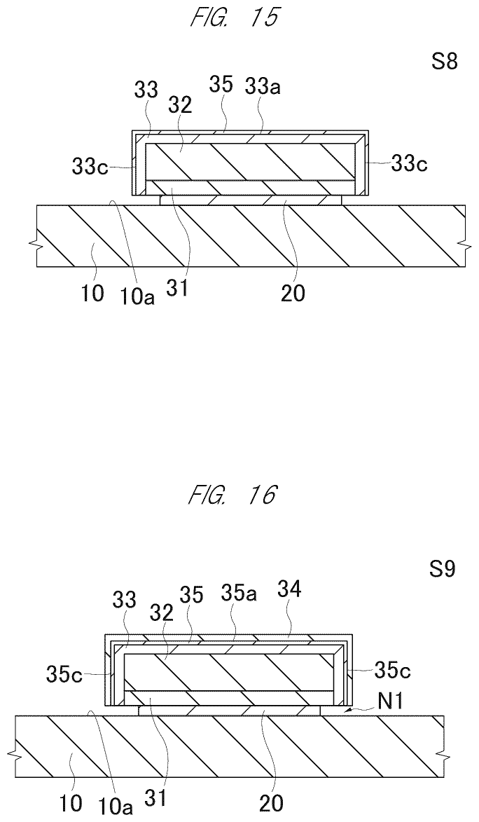

As illustrated in FIG. 15, in step S8, the intermediate layer 35 is formed on the upper surface 33a and the side surface 33c of the third metal layer 33. The intermediate layer 35 is in contact with the upper surface 33a and the side surface 33c of the third metal layer 33. The intermediate layer 35 is formed by, for example, electroless plating. Step S8 is not an indispensable step. In other words, there are cases where the intermediate layer 35 is not formed.

### Forming Fourth Metal Layer 34 on Upper Surface and Side Surface of Intermediate Layer 35

As illustrated in FIG. 16, in step S9, the fourth metal layer 34 is formed on the upper surface 35a and the side surface 35c of the intermediate layer 35. The fourth metal layer 34 is in contact with the upper surface 35a and the side surface 35c of the intermediate layer 35. The fourth metal layer 34 is formed by, for example, electroless plating.

When the intermediate layer 35 is not provided, the fourth metal layer 34 is formed on the upper surface 33a and the side surface 33c of the third metal layer 33. Also, when the intermediate layer 35 is not provided, the fourth metal layer 34 is in contact with the upper surface 33a and the side surface 33c of the third metal layer 33.

As described above, the highly reliable wiring board 1 according to this embodiment can be manufactured by the simple manufacturing method.

### Modification

A method of manufacturing a wiring board according to this embodiment is the same as that of the embodiment described above from step S1 to step S4, and a resist layer other than the resist layer 70 may be formed on a part of the upper surface 31a of the first metal layer 31 after step S4 of forming the first metal layer 31. Thereafter, the second metal layer 32 is formed on the upper surface 31a of the first metal layer 31. The second metal layer 32 is not formed on the part of the upper surface 31a of the first metal layer 31 that is covered with the resist layer. In this way, a place where the second metal layer 32 is not formed can be formed on the upper surface 31a of the first metal layer 31. As a result, it is possible to reduce the thickness of the wiring in the part where the second metal layer 32 is not formed. A metal layer made of, for example, Al or Au is formed on the upper surface 31a of the first metal layer 31 where the second metal layer 32 is not formed.

### Method of Manufacturing Light Emitting Device

Next, a method of manufacturing a light emitting device according to one embodiment will be described. The method of manufacturing the light emitting device according to this embodiment includes the method of manufacturing the wiring board described above. For example, the method of manufacturing the light emitting device according to this embodiment uses the wiring board 1D manufactured by the method of manufacturing the wiring board described above.

The method of manufacturing the light emitting device further includes arranging the light emitting element 210 on the insulating substrate 10 and arranging the reflective member 260 on the upper surface 10a of the insulating substrate 10.

In arranging the light emitting element 210 on the insulating substrate 10, for example, the terminal of the light emitting element 210 is electrically connected to the fourth metal layer 34 by the conductive material 250. For example, the conductive material 250 serves also as a bonding member. More specifically, the light emitting element 210 is fixed onto the fourth metal layer 34 by the conductive material 250.

In arranging the reflective member 260 on the upper surface 10a of the insulating substrate 10, the reflective member 260 is arranged so as to be in contact with the fourth metal layer 34, the third metal layer 33, and the base layer 20.

In the foregoing, the invention made by the inventors of the present invention has been specifically described based on the embodiments, but it is needless to say that the present invention is not limited to the embodiments described above and can be modified in various ways within the range not departing from the gist thereof.

The embodiments according to the present invention can provide a wiring board, a semiconductor device, a light emitting device, a method of manufacturing a wiring board, and a method of manufacturing a light emitting device capable of improving the performance.

What is claimed is:

1. A wiring board comprising:
an insulating substrate;
a base layer arranged on an upper surface of the insulating substrate;
a first metal layer arranged on an upper surface of the base layer and containing a first metal;
a second metal layer arranged on an upper surface of the first metal layer and containing a second metal less noble than the first metal;
a third metal layer arranged on an upper surface and a side surface of the second metal layer and containing the first metal; and
a fourth metal layer arranged on an upper surface and a side surface of the third metal layer and containing a third metal more noble than the first metal,
wherein an entire surface of the second metal layer is covered with the first metal layer and the third metal layer.

2. The wiring board according to claim 1,
wherein an edge of the upper surface of the base layer is located on an inner side relative to an edge of a lower surface of the second metal layer when the upper surface of the insulating substrate is seen in plan view.

3. The wiring board according to claim 2,
wherein a distance from the edge of the upper surface of the base layer to the edge of the lower surface of the second metal layer is 1.0 μm or more and 20.0 μm or less when the upper surface of the insulating substrate is seen in plan view.

4. The wiring board according to claim 1, further comprising an intermediate layer containing a fourth metal between the third metal layer and the fourth metal layer.

5. The wiring board according to claim 1,
wherein the base layer is at least one selected from a single layer such as a Ti layer, a Cu layer, an Au layer, or an Ru layer, a stacked layer containing these, an alloy layer, a stacked layer of a Ti layer and a Cu layer, a stacked layer of a Ti layer and an Au layer, a stacked layer of a Ti layer and an Ag layer, an alloy layer of Ti and Ni, an alloy layer of Ti and W, an alloy layer of Cu and Ni, an alloy layer of Ni and Cr, a stacked layer of a Ti layer and a TiNi layer, a stacked layer of a Ti layer and a TiW layer, a stacked layer of a Ti layer, a TiW layer, and a Cu layer, and a stacked layer of a Ti layer, an Ru layer, and a Cu layer.

6. The wiring board according to claim 1,
wherein the base layer is a layer in which a plurality of layers made of at least one selected from a stacked layer of Ti and Cu, a stacked layer of Ti and Au, a stacked layer of Ti and Ag, an alloy layer of Ti and Ni, an alloy layer of Ti and W, an alloy layer of Cu and Ni, an alloy layer of Ni and Cr, and a Ti layer are stacked.

7. The wiring board according to claim 1,
wherein a thickness of the base layer is 0.1 μm or more and 2.0 μm or less, and the first metal layer and the third metal layer are not in contact with the insulating substrate.

8. The wiring board according to claim 1, further comprising a light reflecting layer covering the fourth metal layer,
wherein a total light reflectance of the light reflecting layer when irradiated with light of 450 nm or more and 460 nm or less is higher than a total light reflectance of the fourth metal layer.

9. The wiring board according to claim 1, further comprising a pad portion electrically connected to the fourth metal layer.

10. The wiring board according to claim 9,
wherein the pad portion includes:
the insulating substrate;
the base layer arranged on the upper surface of the insulating substrate;
the first metal layer arranged on the upper surface of the base layer;
an intermediate layer arranged on the upper surface of the first metal layer; and
the fourth metal layer arranged on an upper surface and a side surface of the intermediate layer.

11. The wiring board according to claim 9,
wherein the pad portion includes:
the insulating substrate;
the base layer arranged on the upper surface of the insulating substrate; and
a fifth metal layer arranged on the upper surface of the base layer and containing a fifth metal less noble than the third metal.

12. A semiconductor device comprising:
the wiring board according to claim 1; and
a semiconductor element arranged on the wiring board.

13. A light emitting device comprising:
the wiring board according to claim 1; and
a light emitting element arranged on the wiring board.

14. The light emitting device according to claim 13, further comprising a reflective member arranged on the upper surface of the insulating substrate,
wherein the reflective member is in contact with the fourth metal layer, the third metal layer, and the base layer.

15. A method of manufacturing a wiring board comprising:
preparing an insulating substrate having a base layer formed on its upper surface;
forming a resist layer on an upper surface of the base layer;
developing and exposing the resist layer such that at least a part of the base layer is exposed from the resist layer;
forming a first metal layer containing a first metal on the upper surface of the base layer exposed from the resist layer;
forming a second metal layer containing a second metal less noble than the first metal on an upper surface of the first metal layer;
removing the resist layer after forming the second metal layer;
removing the base layer after removing the resist layer;
forming a third metal layer containing the first metal on an upper surface and a side surface of the second metal layer; and
forming a fourth metal layer containing a third metal more noble than the first metal on an upper surface and a side surface of the third metal layer.

16. The method of manufacturing the wiring board according to claim 15,
wherein, in removing the base layer, the base layer is etched, so that an edge of the upper surface of the base layer left on the upper surface of the insulating substrate is formed on an inner side relative to an edge of a lower surface of the second metal layer when the upper surface of the insulating substrate is seen in plan view.

17. The method of manufacturing the wiring board according to claim 16,
wherein, in removing the base layer, a distance from the edge of the upper surface of the base layer to the edge of the lower surface of the second metal layer is 1.0 μm or more and 20.0 μm or less when the upper surface of the insulating substrate is seen in plan view.

18. The method of manufacturing the wiring board according to claim 15, further comprising
after forming the third metal layer,
forming an intermediate layer containing a fourth metal on the upper surface and the side surface of the third metal layer,
wherein, in forming the fourth metal layer, the fourth metal layer containing the third metal is formed on an upper surface and a side surface of the intermediate layer.

19. The method of manufacturing the wiring board according to claim 15,
wherein a thickness of the base layer is 0.1 μm or more and 2.0 μm or less in preparing the insulating substrate.

20. A method of manufacturing a light emitting device comprising:
preparing the wiring board according to claim 1;
arranging a light emitting element on the insulating substrate; and
arranging a reflective member on the upper surface of the insulating substrate,
wherein the reflective member is arranged so as to be in contact with the fourth metal layer, the third metal layer, and the base layer in arranging the reflective member.
